(19) United States
(12) Patent Application Publication
(10) Pub. No.: US 2025/0331393 A1
(43) Pub. Date: Oct. 23, 2025

(54) DOUBLE-SIDED DISPLAY PANEL, DRIVING CIRCUIT, DRIVING METHOD, AND DISPLAY DEVICE

(71) Applicant: HKC CORPORATION LIMITED, Shenzhen (CN)

(72) Inventors: Jun SHI, Shenzhen (CN); Dongmei WEI, Shenzhen (CN); Tingting YANG, Shenzhen (CN); Haijiang YUAN, Shenzhen (CN)

(21) Appl. No.: 19/182,655

(22) Filed: Apr. 18, 2025

(30) Foreign Application Priority Data
Apr. 19, 2024 (CN) 202410481960.8

(51) Int. Cl. H10K 59/80; G09G 3/3233; H10K 59/128

(52) U.S. Cl. CPC H10K 59/80517; G09G 3/3233; H10K 59/128; H10K 59/80523; G09G 2300/023; G09G 2300/0842; G09G 2310/08

(57) ABSTRACT

A double-sided display panel, a driving circuit, a driving method, and a display device are disclosed. The double-sided display panel includes a substrate, and a first and a second display panel opposite to each other. The first and the second display panels are arranged on the substrate. A display surface of the first display panel and a display surface of the second display panel are arranged to face away from each other. The first display panel includes a first anode layer, a first light-emitting layer, and a first cathode layer stacked in sequence. The second display panel includes a second anode layer, a second light-emitting layer, and a second cathode layer stacked in sequence. The first and the second anode layers are connected. An orthogonal projection of the first anode layer on the substrate overlaps or coincides with an orthogonal projection of the second anode layer on the substrate.

### CROSS-REFERENCE TO RELATED APPLICATIONS

This application claims the priority and benefit of Chinese patent application number 2024104819608, titled “Double-sided Display Panel, Driving Circuit, Driving Method, and Display Device” and filed Apr. 19, 2024 with China National Intellectual Property Administration, the entire contents of which are incorporated herein by reference.

### TECHNICAL FIELD

This application relates to the field of display technology, and more particularly relates to a double-sided display panel, a driving circuit, a driving method, and a display device.

### BACKGROUND

The description provided in this section is intended for the mere purpose of providing background information related to the present application but doesn't necessarily constitute prior art.

A double-sided display device is a device that can display images on both sides of the display device. It has a wide range of applications, such as: business halls in window industries e.g. the communications industry, government windows, the financial industry, and the transportation industry; public places with large traffic such as airports, railway stations, subway stations, and canteens; electronic products such as digital cameras, video cameras, and mobile phones, etc. Double-sided display devices may be two display panels placed opposite to each other, so that one display panel can be seen on each side for display. Although this achieves double-sided display, its consists in stacking two single-sided display panels, which inevitably brings disadvantages such as large space occupied, high power consumption, and high production cost. Therefore, how to make the double-sided display panel thinner and lighter as a whole and achieve integration of the drivers has become a key issue in the development of the double-sided display panel.

### SUMMARY

It is therefore one purpose of this application to provide a double-sided display panel that is thin and lightweight as a whole, a driving circuit, a driving method, and a display device.

The present application discloses a double-sided display panel, including a substrate, a first display panel and a second display panel arranged opposite to each other. The first display panel and the second display panel are arranged on the substrate. The display surface of the first display panel and the display surface of the second display panel are arranged to face away from each other. The first display panel includes a first anode layer, a first light-emitting layer, and a first cathode layer stacked in sequence. The second display panel includes a second anode layer, a second light-emitting layer, and a second cathode layer stacked in sequence. The first anode layer and the second anode layer are connected to each other. The orthogonal projection of the first anode layer on the substrate overlaps or coincides with the orthogonal projection of the second anode layer on the substrate.

In some embodiments, the first anode layer and the second anode layer are respectively arranged on two sides of the substrate that face away from each other. A through hole is arranged in the substrate. The first anode layer and the second anode layer are connected through the through hole. The first display panel includes a first pixel. The second display panel includes a second pixel. The first pixel and the second pixel are arranged on two sides of the substrate that face away from each other. The first pixel includes a first anode, a first light-emitting element, and a first cathode stacked in sequence. The second pixel includes a second anode, a second light-emitting element, and a second cathode stacked in sequence. The first anode is arranged in the first anode layer. The second anode is arranged in the second anode layer. The first light-emitting element is arranged in the first light-emitting layer. The second light-emitting element is arranged in the second light-emitting layer. The first cathode is arranged in the first cathode layer. The second cathode is arranged in the second cathode layer. The first anode and the second anode are connected through the through hole. The first cathode and the second cathode are independently controlled.

In some embodiments, the first display panel further includes a third pixel. The second display panel further includes a fourth pixel. The third pixel and the fourth pixel are disposed on opposite sides of the substrate. The third pixel is disposed adjacent to the first pixel. The second pixel is disposed adjacent to the fourth pixel. The third pixel includes a third anode, a third light-emitting element, and a third cathode stacked in sequence. The fourth pixel includes a fourth anode, a fourth light-emitting element, and a fourth cathode stacked in sequence. The through hole includes a first through hole and a second through hole. The third anode is disposed in the first anode layer. The fourth anode is disposed in the second anode layer. The third light-emitting element is disposed in the first light-emitting layer. The fourth light-emitting element is disposed in the second light-emitting layer. The third cathode is disposed in the first cathode layer. The fourth cathode is disposed in the second cathode layer. The first anode and the second anode are connected through the first through hole. The third anode and the fourth anode are connected through the second through hole. The first anode and the third anode are not connected to each other, and the second anode and the fourth anode are not connected to each other. The third cathode and the fourth cathode are independently controlled.

In some embodiments, the first cathode layer includes a first cathode and a third cathode arranged in multiple rows or columns at intervals. The first cathode and the third cathode in one row or column are both bar-shaped structures. The second cathode layer includes a second cathode and a fourth cathode arranged in multiple rows or columns at intervals. The second cathode and the fourth cathode in one row or column are both bar-shaped structures.

In some embodiments, the double-sided display panel further includes a data line, which is arranged between the first anode and the substrate. The data line is connected to the first anode layer and connected to the second anode layer through the through hole. The first anode includes a first anode portion and a second anode portion connected to each other. The second anode includes a third anode portion and a fourth anode portion connected to each other. The first through hole is arranged between the first anode and the third anode. The second anode portion and the fourth anode portion are each arranged corresponding to the first through hole and connected through the first through hole. The third anode includes a fifth anode portion and a sixth anode portion connected to each other. The fourth anode includes a seventh anode portion and an eighth anode portion connected to each other. The second through hole is arranged on the side of the third anode facing away from the first anode. The sixth anode portion and the eighth anode portion are each arranged corresponding to the second through hole and connected through the second through hole. The diameters of the first through hole and the second through hole are each 5 μm to 10 μm.

In some embodiments, the first display panel and the second display panel are arranged on the same side of the substrate. The first display panel includes a plurality of overhang structures and a plurality of pixel openings. The plurality of overhang structures are arranged on the substrate at intervals. The plurality of pixel openings are arranged between two adjacent overhang structures in a one-to-one correspondence. The first anode layer and the second anode layer are connected through the overhang structure. The first display panel includes a first pixel. The second display panel includes a second pixel. The first pixel and the second pixel are stacked in sequence and arranged on the same side of the substrate. The first pixel includes a first anode, a first light-emitting element, a first cathode, and a first encapsulation layer stacked in sequence. The second pixel includes a second anode, a second light-emitting element, a second cathode, and a second encapsulation layer stacked in sequence. The first anode is arranged in the first anode layer. The second anode is arranged in the second anode layer. The first light-emitting element is arranged in the first light-emitting layer. The second light-emitting element is arranged in the second light-emitting layer. The first cathode is arranged in the first cathode layer. The second cathode is arranged in the second cathode layer. The first anode and the second anode are connected through the overhang structure. The first cathode and the second cathode are independently controlled.

In some embodiments, the overhang structure includes a pixel de-fining layer, a metal conductive layer, and a shielding layer stacked in sequence. The metal conductive layer includes a first metal conductive layer and a second metal conductive layer. The first metal conductive layer and the second metal conductive layer are arranged on the pixel defining layer at intervals. Part of the shielding layer is located between the first metal conductive layer and the second metal conductive layer. The second anode includes a first anode portion, a first anode connecting portion, and a second anode connecting portion connected to each other. The first anode connecting portion and the second anode connecting portion are arranged opposite to each other and are each connected to the first anode portion. The first anode connecting portion is connected to one end of the first anode through the second metal conductive layer of the n-th overhang structure. The second anode connecting portion is connected to the other end of the first anode through the first metal conductive layer of the (n+1) th overhang structure.

The present application further discloses a driving circuit for the double-sided display panel as described above. The driving circuit includes a first thin film transistor, a second thin film transistor, a storage capacitor, a first organic light emitting element, a second organic light emitting element, a third organic light emitting element, and a fourth organic light emitting element. The gate of the first thin film transistor is electrically connected to a scan line signal. The source of the first thin film transistor is electrically connected to a data line signal. The drain of the first thin film transistor is electrically connected to the gate of the second thin film transistor and the input terminal of the storage capacitor. The source of the second thin film transistor is electrically connected to a constant voltage of a power cable. The drain of the second thin film transistor is connected to the anode of the first organic light emitting element, the anode of the second organic light emitting element, the anode of the third organic light emitting element, and the anode of the fourth organic light emitting element. The output terminal of the storage capacitor is connected to the anode of the first organic light emitting element, the anode of the second organic light emitting element, the anode of the third organic light emitting element, and the anode of the fourth organic light emitting element. The cathode of the first organic light emitting element is connected to a first cathode signal. The cathode of the second organic light emitting element is connected to a second cathode signal. The cathode of the third organic light emitting element is connected to a third cathode signal. The cathode of the fourth organic light emitting element is connected to a fourth cathode signal. The first cathode signal, the second cathode signal, the third cathode signal and the fourth cathode signal are independently controlled.

The present application further discloses a driving method for the driving circuit as described above, comprising the following operations:
the scan signal scans the n-th scan line, and the first thin film transistor is turned on; the data line charges the storage capacitor through the first thin film transistor, and at the same time controls the second thin film transistor to operate in a saturation region, and the constant voltage signal connected to the power cable outputs a driving current through the second thin film transistor;
the first thin film transistor is turned off, the storage capacitor is discharged to make the second thin film transistor continue to operate in the saturation region, and the constant voltage signal connected to the power cable outputs the driving current through the second thin film transistor;
where when the first cathode signal, the second cathode signal, the third cathode signal and the fourth cathode signal are all powered, and the power supply voltages are consistent, then the two sides of the double-sided display panel display the same image;
when the first cathode signal is powered, the second cathode signal is powered off, the third cathode signal is powered off, the fourth cathode signal is powered, and the power supply voltages of the first cathode signal and the third cathode signal are different, then the first display panel and the second display panel display different images;
when the first cathode signal is powered, the second cathode signal is powered off, the third cathode signal is powered, the fourth cathode signal is powered off, and the power supply voltages of the first cathode signal and the third cathode signal are the same, then the first display panel displays an image;
when the first cathode signal is powered off, the second cathode signal is powered, the third cathode signal is powered off, the fourth cathode signal is powered, and the power supply voltages of the second cathode signal and the fourth cathode signal are the same, the second display panel displays an image.

The present application further discloses a display device, including the double-sided display panel as described above.

Compared with the double-sided display panel in the related art, which is formed by simply stacking two single-sided display panels, the double-sided display panel of the present application includes a first display panel and a second display panel arranged opposite to each other. The display surface of the first display panel and the display surface of the second display panel are arranged to face away from each other. The first display panel includes a first anode layer, a first light-emitting layer, and a first cathode layer stacked in sequence. The second display panel includes a second anode layer, a second light-emitting layer, and a second cathode layer stacked in sequence. The first anode layer and the second anode layer are connected to each other. An orthogonal projection of the first anode layer on the substrate overlaps or coincides with an orthogonal projection of the second anode layer on the substrate. In this way, the first display panel and second display panel share anode layer signals. As such, the first anode layer and second anode layer can be connected simultaneously through only one data line to transmit data signals, thereby reducing the wiring in the display panel and further reducing the space occupied by the wiring, making the display panel lighter and thinner overall while achieving double-sided display.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a block diagram of a display device according to the present application.

FIG. 2 is a cross-sectional schematic diagram of the double-sided display panel according to a first embodiment of the present application.

FIG. 3 is a partial enlarged schematic diagram of portion A shown in FIG. 2.

FIG. 4 is a schematic diagram illustrating a distribution of a first cathode layer of a first display panel or a second cathode layer of a second display panel according to the first embodiment of the present application.

FIG. 5 is a schematic diagram of a driving circuit according to the first embodiment of the present application.

FIG. 6 is a timing diagram of FIG. 5.

FIG. 7 is a schematic diagram of an operating mode of the double-sided display panel according to the first embodiment of the present application.

FIG. 8 is a flowchart of a driving method according to the present application.

FIG. 9 is a cross-sectional schematic diagram of a double-sided display panel according to a second embodiment of the present application.

FIG. 10 is a partial enlarged schematic diagram of portion B shown in FIG. 9.

In the drawings: 10, display device; 100, double-sided display panel; 110, first display panel; 111, first anode layer; 112, first light-emitting layer; 113, first cathode layer; 114, first pixel; 115, first anode; 116, first light-emitting element; 117, first cathode; 118, third pixel; 119, third anode; 120, third light-emitting element; 121, third cathode; 122, first anode portion; 123, second anode portion; 124, fifth anode portion; 125, sixth anode portion; 130, second display panel; 131, second anode layer; 132, second light-emitting layer; 133, second cathode layer; 134, second pixel; 135, second anode; 136, second light-emitting element; 137, second cathode; 138, fourth pixel; 139, fourth anode; 140, fourth light-emitting element; 141, fourth cathode; 142, third anode portion; 143, fourth anode portion; 144, seventh anode portion; 145, eighth anode portion; 146, first anode connecting portion; 147, second anode connecting portion; 150, substrate; 151, through hole; 152, first through hole; 153, second through hole; 160, data line; 170, overhang structure; 171, pixel defining layer; 172, metal conductive layer; 173, shielding layer; 174, first metal conductive layer; 175, second metal conductive layer; 176, first encapsulation layer; 177, second encapsulation layer; 178, planarization layer; 179, first guide hole; 180, second guide hole; 200, driving circuit; 210, first thin film transistor; 220, second thin film transistor; 230, storage capacitor; 240, first organic light emitting element; 250, second organic light emitting element; 260, third organic light emitting element; 270, fourth organic light emitting element; 280, scan line.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

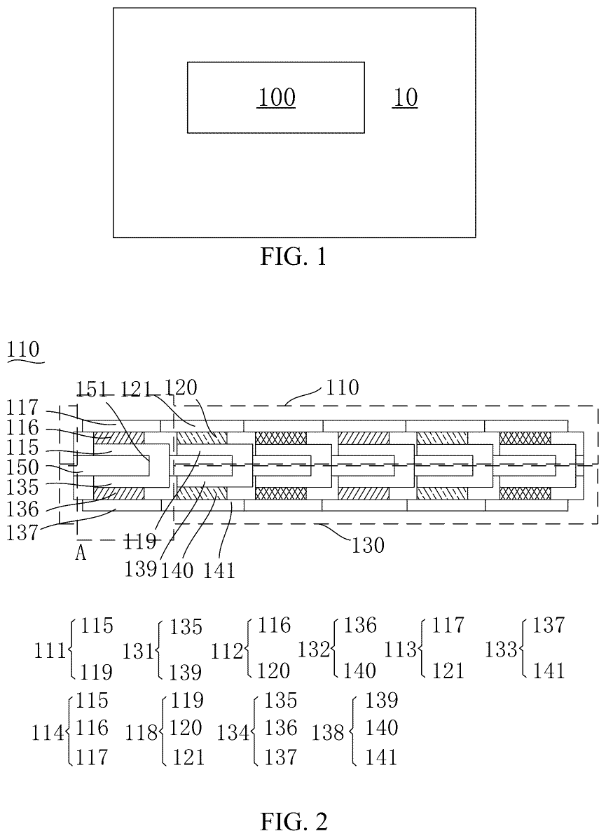

FIG. 1 is a block diagram of a display device according to the present application. As shown in FIG. 1, the present application discloses a display device 10, including a double-sided display panel 100. FIG. 2 is a cross-sectional schematic diagram of a double-sided display panel according to the first embodiment of the present application. As shown in FIG. 2, the double-sided display panel 100 includes a substrate 150, and a first display panel 110 and a second display panel 130 that are arranged opposite to each other. The first display panel 110 and the second display panel 130 are arranged on the substrate 150. A display surface of the first display panel 110 and a display surface of the second display panel 130 are arranged to face away from each other. The first display panel 110 includes a first anode layer 111, a first light-emitting layer 112, and a first cathode layer 113 stacked in sequence. The second display panel 130 includes a second anode layer 131, a second light-emitting layer 132, and a second cathode layer 133 which are stacked in sequence. The first anode layer 111 is connected to the second anode layer 131. An orthogonal projection of the first anode layer 111 on the substrate 150 overlaps or coincides with an orthogonal projection of the second anode layer 131 on the substrate 150.

Compared with the double-sided display panel 100 in the prior art, which is formed by simply stacking two single-sided display panels, the double-sided display panel 100 of the present application includes a first display panel 110 and a second display panel 130 arranged opposite to each other. The display surface of the first display panel 110 and the display surface of the second display panel 130 are arranged to face away from each other. The first display panel 110 includes a first anode layer 111, a first light-emitting layer 112, and a first cathode layer 113 stacked in sequence. The second display panel 130 includes a second anode layer 131, a second light-emitting layer 132, and a second cathode layer 133 stacked in sequence. The first anode layer 111 and the second anode layer 131 are connected to each other. An orthogonal projection of the first anode layer 111 on the substrate 150 overlaps or coincides with an orthogonal projection of the second anode layer 131 on the substrate 150. In this way, the first display panel 110 and second display panel 130 share anode layer signals. As such, the first anode layer 111 and second anode layer 131 can be connected simultaneously through only one data line 160 to transmit data signals, thereby reducing the wiring in the display panel and further reducing the space occupied by the wiring, making the display panel lighter and thinner overall while achieving double-sided display.

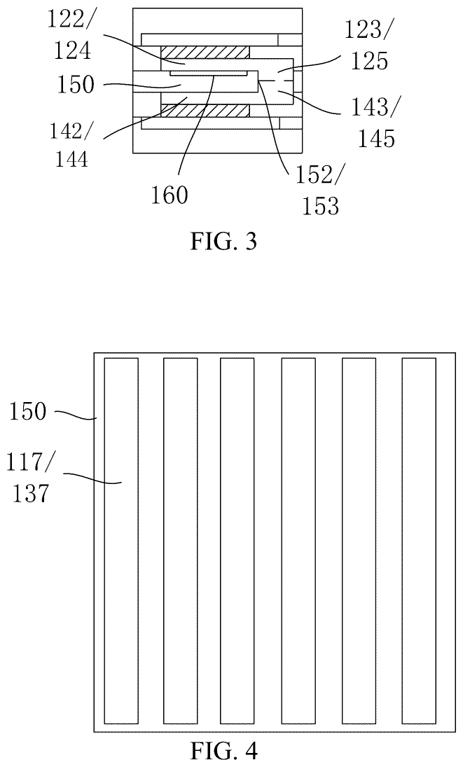

FIG. 3 is a partial enlarged schematic diagram of portion A shown in FIG. 2. In connection with FIG. 2 and FIG. 3, it can be seen that the first anode layer 111 and the second anode layer 131 are respectively arranged on two sides of the substrate 150 that face away from each other. A through hole 151 is arranged in the substrate 150. The first anode layer 111 and the second anode layer 131 are connected through the through hole 151. The first display panel 110 includes a first pixel 114. The second display panel 130 includes a second pixel 134. The first pixel 114 and the second pixel 134 are arranged on two sides of the substrate 150 that face away from each other. The first pixel 114 includes a first anode 115, a first light-emitting element 116, and a first cathode 117 that are stacked in sequence. The second pixel 134 includes a second anode 135, a second light-emitting element 136, and a second cathode 137 that are stacked in sequence. The first anode 115 is arranged in the first anode layer 111. The second anode 135 is arranged in the second anode layer 131. The first light-emitting element 116 is arranged in the first light-emitting layer 112. The second light-emitting element 136 is arranged in the second light-emitting layer 132. The first cathode 117 is arranged in the first cathode layer 113. The second cathode 137 is arranged in the second cathode layer 133. The first anode 115 and the second anode 135 are connected through the through hole 151. The first cathode 117 and the second cathode 137 are independently controlled. In this way, by adjusting the voltage levels of the first cathode 117 and the second cathode 137, the first display panel 110 and the second display panel 130 can display the same image, but the brightness may be different.

Of course, the first display panel 110 further includes a third pixel 118, and the second display panel 130 further includes a fourth pixel 138. The third pixel 118 and the fourth pixel 138 are arranged on both sides of the substrate 150 that face away from each other. The third pixel 118 is arranged adjacent to the first pixel 114, and the second pixel 115 is arranged adjacent to the fourth pixel 138. The third pixel 118 includes a third anode 119, a third light-emitting element 120, and a third cathode 121 that are stacked in sequence. The fourth pixel 138 includes a fourth anode 139, a fourth light-emitting element 140, and a fourth cathode 141 that are stacked in sequence. The through hole 151 includes a first through hole 152 and a second through hole 153. The third anode 119 is arranged in the first anode layer 111. The fourth anode 139 is arranged in the second anode layer 131. The third light-emitting element 120 is arranged in the first light-emitting layer 112. The fourth light-emitting element 140 is arranged in the second light-emitting layer 132. The third cathode 121 is arranged in the first cathode layer 113. The fourth cathode 141 is arranged in the second cathode layer 133.

The first anode 115 and the second anode 135 are connected through the first through hole 152. The third anode 119 and the fourth anode 139 are connected through the second through hole 153. The first anode 115 and the third anode 119 are not connected to each other. The second anode 135 and the fourth anode 139 are not connected to each other. The third cathode 121 and the fourth cathode 141 are independently controlled. In this way, the pixels of the first display panel 110 and the second display panel 130 can all be lit, and the two display panels may display the same image. It is also possible to drive the first pixel 114 to light up, while the second pixel 134 is not lit, the third pixel 118 is not lit, and the fourth pixel 138 is lit, so as to display different images. Of course, the first pixel 114 may not be lit, the second pixel 134 may be lit, the third pixel 118 may be lit, and the fourth pixel 138 may not be lit, so that different images may be displayed, depending on the actual selection. In addition, the first display panel further includes a fifth pixel, and the second display panel further includes a sixth pixel. The first pixel and the second pixel may both be red. The third pixel and the fourth pixel may both be green. The fifth pixel and the sixth pixel may both be blue. The colors of the pixels of the first display panel and the pixels of the second display panel may be adjusted according to actual needs, and are not limited herein.

FIG. 4 is a schematic diagram illustrating a distribution of a first cathode layer of the first display panel or a second cathode layer of the second display panel according to the first embodiment of the present application. As shown in FIG. 4, the cathode in each display panel is an integral structure. That is, the first cathode layer 113 includes a first cathode 117 and a third cathode 121 arranged in multiple rows or columns. The first cathode 117 and the third cathode 121 in one row or one column are both bar-shaped structures. The second cathode layer 133 includes a second cathode 137 and a fourth cathode 141 arranged in multiple rows or columns. The second cathode 137 and the fourth cathode 141 in one row or one column are both bar-shaped structures. In this way, it is only required to connect the first cathode 117 with the third cathode 121 or connect the second cathode 137 with the fourth cathode 141 once, which not only simplifies the manufacturing process but also reduces the number of circuit connections. The third cathode 121 and the fourth cathode 141 are also bar-shaped structures. That is, the first cathode layer 113 includes a plurality of first cathodes 117 arranged at intervals. The second cathode layer 133 includes a plurality of second cathodes 137 arranged at intervals. The third cathode 121 is the first cathode 117. The fourth cathode 141 is the second cathode 137. The first anode 115, the first cathode 117, the second anode 135, and the second cathode 137 may all be made of transparent electrode materials, so that the double-sided display panel 100 is a transparent display panel to achieve a double-sided display effect.

As shown in FIG. 3, the double-sided display panel 100 further includes a data line 160. The data line 160 is disposed between the first anode 115 and the substrate 150. The data line 160 is connected to the first anode layer 111 and further connected to the second anode layer 131 through the through hole 151, and a data signal voltage is input through the data line 160.

The first anode 115 includes a first anode portion 122 and a second anode portion 123 connected to each other. The second anode 135 includes a third anode portion 142 and a fourth anode portion 143 connected to each other. The first through hole 152 is arranged between the first anode 115 and the third anode 119. The second anode portion 123 and the fourth anode portion 143 are each arranged corresponding to the first through hole 152 and are connected through the first through hole 152.

The third anode 119 includes a fifth anode portion 124 and a sixth anode portion 125 connected to each other. The fourth anode 139 includes a seventh anode portion 144 and an eighth anode portion 145 connected to each other. The second through hole 153 is disposed on the side of the third anode 119 facing away from the first anode 115. The sixth anode portion 125 and the eighth anode portion 145 are each arranged corresponding to the second through hole 153 and are connected through the second through hole 153.

The diameters of the first through hole 152 and the second through hole 153 are both 5 μm to 10 μm, which can ensure the reliability of the connection between the two anodes. The spacing between the first anode 115 and the third anode 119, and the spacing between the second anode 135 and the fourth anode 139 are both 5 μm to 10 μm. In this way, after making the through hole 151 in the substrate 150, while ensuring the reliability of the connection between the upper and lower anodes, the overall support strength of the substrate 150 can also be guaranteed to achieve a stable effect.

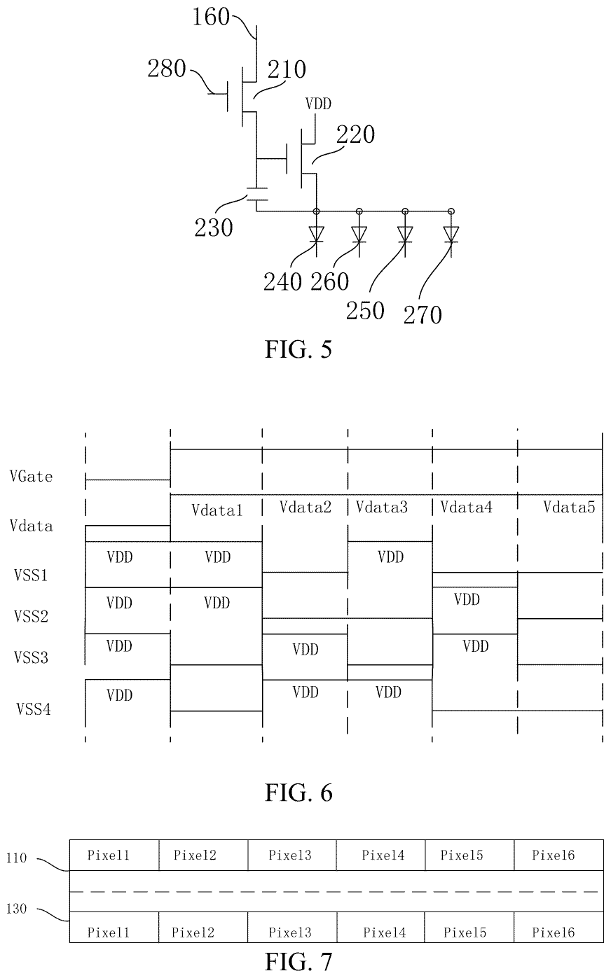

FIG. 5 is a schematic diagram of a driving circuit according to the first embodiment of the present application. FIG. 6 is a timing diagram of FIG. 5. As shown in FIG. 5, the present application further discloses a driving circuit 200 for the double-sided display panel 100 as described above. The driving circuit 200 includes a first thin film transistor 210, a second thin film transistor 220, a storage capacitor 230, a first organic light emitting element 240, a second organic light emitting element 250, a third organic light emitting element 260, and a fourth organic light emitting element 270. A gate of the first thin film transistor 210 is electrically connected to a signal of the scan line 280. A source of the first thin film transistor 210 is electrically connected to a signal of the data line 160. A drain of the first thin film transistor 210 is electrically connected to a gate of the second thin film transistor 220 and an input terminal of the storage capacitor 230. A source of the second thin film transistor 220 is electrically connected to a constant voltage of a power cable. A drain of the second thin film transistor 220 is connected to an anode of the first organic light emitting element 240, an anode of the second organic light emitting element 250, an anode of the third organic light emitting element 260, and an anode of the fourth organic light emitting element 270.

An output terminal of the storage capacitor 230 is connected to an anode of the first organic light emitting element 240, an anode of the second organic light emitting element 250, an anode of the third organic light emitting element 260, and an anode of the fourth organic light emitting element 270. A cathode of the first organic light emitting element 240 is connected to a first cathode signal. A cathode of the second organic light emitting element 250 is connected to a second cathode signal. A cathode of the third organic light emitting element 260 is connected to a third cathode signal. A cathode of the fourth organic light emitting element 270 is connected to a fourth cathode signal. The first cathode signal, the second cathode signal, the third cathode signal, and the fourth cathode signal are controlled independently of each other.

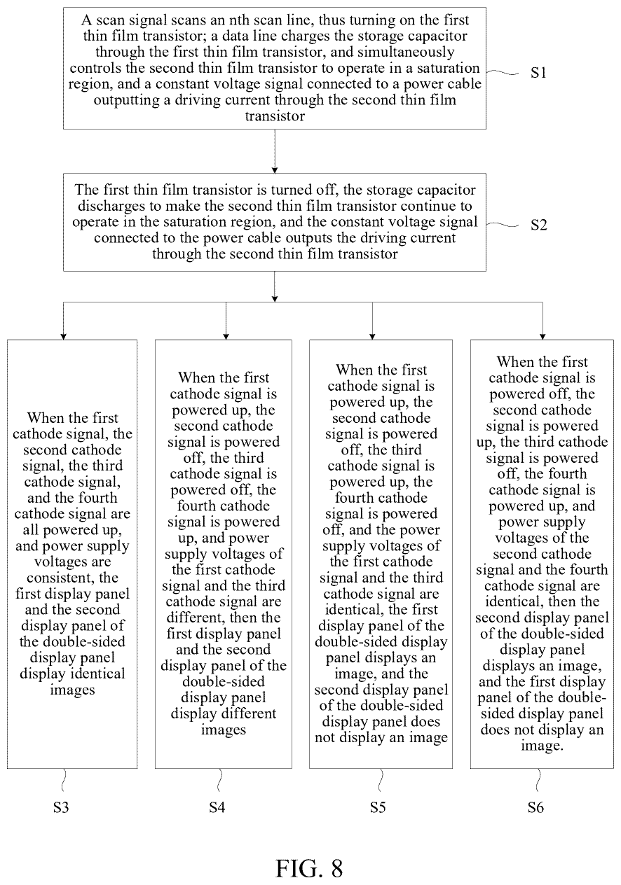

FIG. 7 is a schematic diagram of an operating mode of the double-sided display panel according to the first embodiment of the present application. FIG. 8 is a flowchart of a driving method according to the present application. As shown in FIG. 8, the present application further discloses a driving method for the driving circuit 200 as described above, the driving method including the following operations:
S1: in which the scan signal scans the n-th scan line, and the first thin film transistor is turned on; the data line charges the storage capacitor through the first thin film transistor, and at the same time controls the second thin film transistor to operate in a saturation region, and a constant voltage signal connected to the power cable outputs a driving current through the second thin film transistor.
S2: in which the first thin film transistor is turned off, the storage capacitor discharges to make the second thin film transistor continue to operate in the saturation region, and the constant voltage signal connected to the power cable outputs the driving current through the second thin film transistor.
S3: when the first cathode signal, the second cathode signal, the third cathode signal, and the fourth cathode signal are all powered, and their power supply voltages are consistent, then the first display panel and the second display panel of the double-sided display panel display the same image.

In connection with FIGS. 6 and 7, the scan signal Gate is a high voltage, and the data signal data is Vdata5 at this time. The storage capacitor 230 stores Vdata5 and turns on the first thin film transistor 210. At this time, the first cathode signal VSS1 through fourth cathode signal VSS4 are all low level, and all the light-emitting element pixels of the first display panel 110 and the second display panel 130 are all emitting light. Vdata5 controls the light-emitting brightness of all the above light-emitting elements in a time-sharing manner. At this time, the display brightness of the double-sided display is the maximum.
S4: when the first cathode signal is powered, the second cathode signal is powered off, the third cathode signal is powered off, and the fourth cathode signal is powered, and the power supply voltages of the first cathode signal and the third cathode signal are different, then the first display panel and the second display panel of the double-sided display panel display different images.

In connection with FIGS. 6 and 7, the scan signal Gate is a high voltage, and the data signal data is Vdata4 at this time. The storage capacitor 230 stores Vdata4 and turns on the second thin film transistor 220. At this time, the third cathode signal VSS2=the second cathode signal VSS3=constant voltage VDD, the first cathode signal VSS1 and the fourth cathode signal VSS4 are both low level, and the light-emitting elements pixel 1, 3, 5, etc. of the first display panel 110 emit light together. The light-emitting elements pixel2, 4, 6, etc. of the second display panel 130 emit light together. Vdata4 controls the brightness of the above light-emitting elements in a time-sharing manner, so that the first display panel 110 displays a first image and the second display panel 130 displays a second image. Alternatively, the scan signal Gate is a high voltage, and the data signal data is Vdata3, the storage capacitor 230 stores Vdata3, and the second thin film transistor 220 is turned on. At this time, the first cathode signal VSS1=fourth cathode signal VSS4=the constant voltage VDD, the third cathode signal VSS2 and the second cathode signal VSS3 are both low level, so the light-emitting elements pixel 2, 4, 6, etc. of the first display panel 110 emit light together. The light-emitting elements pixel 1, 3, 5, etc. of the second display panel 130 emit light together. Vdata3 controls the brightness of the above light-emitting elements in a time-sharing manner, so that the first display panel 110 displays a first image and the second display panel 130 displays a second image.
S5: when the first cathode signal is powered, the second cathode signal is powered off, the third cathode signal is powered, the fourth cathode signal is powered off, and the power supply voltages of the first cathode signal and the third cathode signal are equal, then the first display panel of the double-sided display panel displays an image, while the second display panel of the double-sided display panel does not display an image.

In connection with FIG. S. 6 and 7, the scan signal Gate is a high voltage, and the data signal data is Vdata2 at this time. The storage capacitor 230 stores Vdata2 and turns on the second thin film transistor 220. At this time, the second cathode signal VSS3=fourth cathode signal VSS4=the constant voltage VDD, the first cathode signal VSS1 and the third cathode signal VSS2 are low levels, and the light-emitting element pixels of the second display panel 130 are not emitting light, forming a light-isolating layer. Therefore, the light-emitting element pixels of the first display panel 110 emit light, and Vdata2 controls the light-emitting brightness of all the light-emitting elements Pixels of the first display panel 110 in a time-sharing manner, so that the first display panel 110 displays an image, while the second display panel 130 does not display an image.
S6: when the first cathode signal is powered off, the second cathode signal is powered on, the third cathode signal is powered off, the fourth cathode signal is powered on, and the power supply voltages of the second cathode signal and the fourth cathode signal are the same, then the second display panel of the double-sided display panel displays an image, while the first display panel of the double-sided display panel does not display an image.

In connection with FIGS. 6 and 7, the scan signal Gate is a high voltage, and the data signal data is Vdata1 at this time. The storage capacitor 230 stores Vdatal and turns on the second thin film transistor 220. At this time, the first cathode signal VSS1=third cathode signal VSS2=VDD, the second cathode signal VSS3 and the fourth cathode signal VSS4 are low level, then the light-emitting element pixels of the first display panel 110 are not bright, forming a light-isolating layer. The light-emitting element pixels of the second display panel 130 emit light. Vdata1 controls the light-emitting brightness of the light-emitting element Pixels of the second display panel 130 in a time-sharing manner, so that the first display panel 110 does not display an image, while the second display panel 130 displays an image.

### Second Embodiment

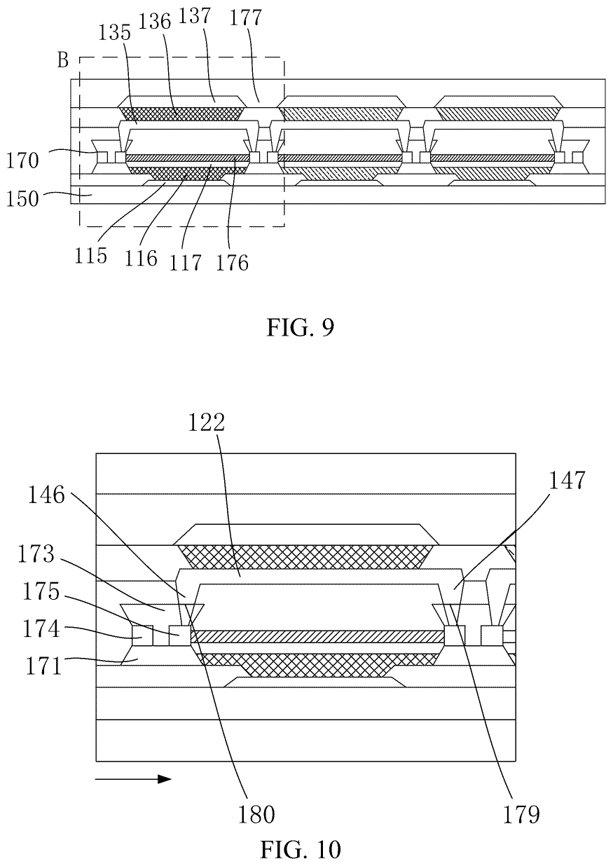

FIG. 9 is a schematic cross-sectional view of a double-sided display panel 100 according to a second embodiment of the present application. FIG. 10 is a partially enlarged schematic view of portion B shown in FIG. 9. As shown in FIG. 9 to FIG. 10, as the second embodiment of the present application, this embodiment is different from the first embodiment in that the first display panel 110 and the second display panel 130 are arranged on the same side of the substrate 150. The first display panel 110 includes a plurality of overhang structures 170 and a plurality of pixel openings. The plurality of overhang structures 170 are arranged at intervals on the substrate 150. The plurality of pixel openings are arranged one by one between two adjacent overhang structures 170. The first anode layer 111 and the second anode layer 131 are connected through the overhang structure 170.

The first display panel 110 includes a first pixel 114. The second display panel 130 includes a second pixel 134. The first pixel 114 and the second pixel 134 are stacked in sequence on the same side of the substrate 150. The first pixel 114 includes a first anode 115, a first light-emitting element 116, a first cathode 117, and a first encapsulation layer 176 stacked in sequence. The second pixel 134 includes a second anode 135, a second light-emitting element 136, a second cathode 137, and a second encapsulation layer 177 stacked in sequence. The first anode 115 is arranged in the first anode layer 111. The second anode 135 is arranged in the second anode layer 131. The first light-emitting element 116 is arranged in the first light-emitting layer 112. The second light-emitting element 136 is arranged in the second light-emitting layer 132. The first cathode 117 is disposed in the first cathode layer 113. The second cathode 137 is disposed in the second cathode layer 133. The first anode 115 and the second anode 135 are connected via the overhang structure 170. The first cathode 117 and the second cathode 137 are independently controlled. In this way, it is not required to drill holes in the substrate 150, but the connection of the upper and lower anode signals can be achieved through the overhang structure 170.

Specifically, as shown in FIG. 10, the first overhang structure 170 and the second overhang structure 170 on the substrate 150 are used as examples for explanation. The overhang structure 170 includes a pixel defining layer 171, a metal conductive layer 172, and a shielding layer 173 stacked in sequence. The metal conductive layer 172 includes a first metal conductive layer 174 and a second metal conductive layer 175. The first metal conductive layer 174 and the second metal conductive layer 175 are arranged in the pixel defining layer 171 at intervals. Part of the shielding layer 173 is located between the first metal conductive layer 174 and the second metal conductive layer 175 to isolate the first metal conductive layer 174 and the second metal conductive layer 175 from being connected, and to prevent the signals of the two adjacent first anodes 115 in the first anode layer 111 from being connected. The second anode 135 includes a first anode portion 122, a first anode connecting portion 146, and a second anode connecting portion 147 that are connected to each other. The first anode connecting portion 146 and the second anode connecting portion 147 are arranged opposite to each other and are each connected to the first anode portion 122. The first anode connecting portion 146 is connected to one end of the first anode 115 through the second metal conductive layer 175 of the n-th overhang structure 170. The second anode connecting portion 147 is connected to the other end of the first anode 115 through the first metal conductive layer 174 of the (n+1)-th overhang structure 170. Similarly, the other anodes of the second anode layer 131 are connected to the anodes of the first anode layer 111 through the above connection method. Both the first anode and the second anode may be made of opaque materials. Because the overhang structure 170 is made first, and then the red light-emitting element is made to directly contact the anode, and because the green light-emitting element is also made later, a first encapsulation layer is necessary to protect the light-emitting material of the red light-emitting element.

The shielding layer 173 may be punched with holes, that is, the shielding layer 173 may be defined with a first guide hole 179 and a second guide hole 180. The first anode connecting portion 146 is connected to the second metal conductive layer 175 through the second guide hole 180 of the first overhang structure 170. The second anode connecting portion 147 is connected to the first metal conductive layer 174 through the first guide hole 179 of the second overhang structure 170. The arrow in the figure indicates the direction of arrangement of the overhang structure 170. Along the direction of arrangement of the overhang structure 170, the diameter of the first guide hole 179 and the diameter of the second guide hole 180 are each ⅕-¼ of the width of the shielding layer 173, ensuring the reliability of the connection without damaging the function of the shielding layer 173.

As shown in FIG. 10, a planarization layer 178 is further arranged between the first display panel 110 and the second display panel 130, which may be used for the subsequent production of a driving backplate. In addition, in this embodiment, the data line 160 is disposed between the second anode layer 131 and the planarization layer 178.

The driving method of the driving circuit 200 is the same as that of the first embodiment, and will not be described in detail herein.

It should be noted that the limitations of the various steps involved in this solution are not to be interpreted to limit the order of the steps, under the premise of not affecting the implementation of the specific solution. The steps written earlier can be executed first, or later, or even at the same time with the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A double-sided display panel, comprising a substrate, and further comprising a first display panel and a second display panel that are arranged opposite to each other; wherein the first display panel and the second display panel are arranged on the substrate; wherein a display surface of the first display panel and a display surface of the second display panel are arranged to face away from each other; wherein the first display panel comprises a first anode layer, a first light-emitting layer, and a first cathode layer that are stacked in sequence, and wherein the second display panel comprises a second anode layer, a second light-emitting layer, and a second cathode layer that are stacked in sequence;
wherein the first anode layer and the second anode layer are connected to each other; wherein an orthogonal projection of the first anode layer on the substrate overlaps or coincides with an orthogonal projection of the second anode layer on the substrate.

2. The double-sided display panel as recited in claim 1, wherein the first anode layer and the second anode layer are respectively arranged on two sides of the substrate that face away from each other, wherein there is defined a through hole in the substrate, wherein the first anode layer and the second anode layer are connected through the through hole;
wherein the first display panel comprises a first pixel, wherein the second display panel comprises a second pixel, wherein the first pixel and the second pixel are arranged on opposite sides of the substrate; wherein the first pixel comprises a first anode, a first light-emitting element, and a first cathode that are stacked in sequence; wherein the second pixel comprises a second anode, a second light-emitting element, and a second cathode that are stacked in sequence; wherein the first anode is arranged in the first anode layer, wherein the second anode is arranged in the second anode layer, wherein the first light-emitting element is arranged in the first light-emitting layer, wherein the second light-emitting element is arranged in the second light-emitting layer, wherein the first cathode is arranged in the first cathode layer, wherein the second cathode is arranged in the second cathode layer; wherein the first anode and the second anode are connected through the through hole; wherein the first cathode and the second cathode are independently controlled.

3. The double-sided display panel as recited in claim 2, wherein the first display panel further comprises a third pixel, wherein the second display panel further comprises a fourth pixel; wherein the third pixel and the fourth pixel are arranged on the two sides of the substrate that face away from each other; wherein the third pixel is arranged adjacent to the first pixel, wherein the second pixel is arranged adjacent to the fourth pixel; wherein the third pixel comprises a third anode, a third light-emitting element, and a third cathode that are stacked in sequence; wherein the fourth pixel comprises a fourth anode, a fourth light-emitting element, and a fourth cathode that are stacked in sequence; wherein the through hole comprises a first through hole and a second through hole; wherein the third anode is arranged in the first anode layer, wherein the fourth anode is arranged in the second anode layer, wherein the third light-emitting element is arranged in the first light-emitting layer, wherein the fourth light-emitting element is arranged in the second light-emitting layer, wherein the third cathode is arranged in the first cathode layer, wherein the fourth cathode is arranged in the second cathode layer;
wherein the first anode and the second anode are connected through the first through hole, wherein the third anode and the fourth anode are connected through the second through hole; and wherein the first anode and the third anode are not connected to each other, wherein the second anode and the fourth anode are not connected to each other; wherein the third cathode and the fourth cathode are independently controlled.

4. The double-sided display panel as recited in claim 3, wherein the first cathode layer comprises the first cathode and the third cathode alternately arranged in a plurality of rows or columns, and wherein the first cathode and the third cathode in each row or column are each a bar-shaped structure; wherein the second cathode layer comprises the second cathode and the fourth cathode alternately arranged in a plurality of rows or columns, and wherein the second cathode and the fourth cathode in each row or column are each a bar-shaped structure.

5. The double-sided display panel as recited in claim 4, further comprising a data line arranged between the first anode and the substrate; wherein the data line is connected to the first anode layer, and is connected to the second anode layer through the through hole;
wherein the first anode comprises a first anode portion and a second anode portion connected to each other, wherein the second anode comprises a third anode portion and a fourth anode portion connected to each other; wherein the first through hole is disposed between the first anode and the third anode, wherein the second anode portion and the fourth anode portion are each disposed corresponding to the first through hole and are connected to each other through the first through hole;
wherein the third anode comprises a fifth anode portion and a sixth anode portion connected to each other, wherein the fourth anode comprises a seventh anode portion and an eighth anode portion connected to each other; wherein the second through hole is disposed on a side of the third anode facing away from the first anode, wherein the sixth anode portion and the eighth anode portion are each disposed corresponding to the second through hole and are connected to each other through the second through hole;
wherein a diameter of each of the first through hole and the second through hole lies in the range of 5 μm to 10 μm.

6. The double-sided display panel as recited in claim 5, wherein the first display panel and the second display panel are arranged on a same side of the substrate; wherein the first display panel comprises a plurality of overhang structures and a plurality of pixel openings; wherein the plurality of overhang structures are arranged on the substrate at intervals; wherein the plurality of pixel openings are each disposed between respective two adjacent overhang structures; wherein the first anode layer and the second anode layer are connected through the plurality of overhang structures;
wherein the first display panel comprises a first pixel, wherein the second display panel comprises a second pixel; wherein the first pixel and the second pixel are stacked in sequence on a same side of the substrate; wherein the first pixel comprises a first anode, a first light-emitting element, a first cathode, and a first encapsulation layer that are stacked in sequence; wherein the second pixel comprises a second anode, a second light-emitting element, a second cathode, and a second encapsulation layer that are stacked in sequence; wherein the first anode is arranged in the first anode layer, wherein the second anode is arranged in the second anode layer, wherein the first light-emitting element is arranged in the first light-emitting layer, wherein the second light-emitting element is arranged in the second light-emitting layer, wherein the first cathode is arranged in the first cathode layer, wherein the second cathode is arranged in the second cathode layer; wherein the first anode and the second anode are connected through a respective overhang structure, wherein the first cathode and the second cathode are independently controlled.

7. The double-sided display panel as claimed in claim 6, wherein the overhang structure comprises a pixel defining layer, a metal conductive layer, and a shielding layer that are stacked in sequence, wherein the metal conductive layer comprises a first metal conductive layer and a second metal conductive layer, wherein the first metal conductive layer and the second metal conductive layer are arranged on the pixel defining layer at intervals, and wherein a part of the shielding layer is disposed between the first metal conductive layer and the second metal conductive layer, wherein the second anode comprises a first anode portion, a first anode connecting portion, and a second anode connecting portion that are connected to each other, wherein the first anode connecting portion and the second anode connecting portion are arranged opposite to each other and are each connected to the first anode portion, wherein the first anode connecting portion is connected to one end of the first anode through the second metal conductive layer of an n-th overhang structure, wherein the second anode connecting portion is connected to another end of the first anode through the first metal conductive layer of an (n+1)-th overhang structure.

8. A driving circuit for the double-sided display panel as recited in claim 1, wherein the driving circuit comprises a first thin film transistor, a second thin film transistor, a storage capacitor, a first organic light emitting element, a second organic light emitting element, a third organic light emitting element, and a fourth organic light emitting element; wherein a gate of the first thin film transistor is electrically connected to a scan line signal, wherein a source of the first thin film transistor is electrically connected to a data line signal, wherein a drain of the first thin film transistor is electrically connected to a gate of the second thin film transistor and an input terminal of the storage capacitor; wherein a source of the second thin film transistor is electrically connected to a constant voltage of a power cable, wherein a drain of the second thin film transistor is connected to an anode of the first organic light emitting element, an anode of the second organic light emitting element, an anode of the third organic light emitting element, and an anode of the fourth organic light emitting element;
wherein an output terminal of the storage capacitor is connected to the anode of the first organic light emitting element, the anode of the second organic light emitting element, the anode of the third organic light emitting element, and the anode of the fourth organic light emitting element; wherein a cathode of the first organic light emitting element is connected to a first cathode signal, wherein a cathode of the second organic light emitting element is connected to a second cathode signal, wherein a cathode of the third organic light emitting element is connected to a third cathode signal, wherein a cathode of the fourth organic light emitting element is connected to a fourth cathode signal; and wherein the first cathode signal, the second cathode signal, the third cathode signal, and the fourth cathode signal are independently controlled.

9. A driving method, used in the driving circuit as recited in claim 8, the driving method comprising:
an operation in which a scan signal scans an n-th scan line, thus turning on the first thin film transistor; a data line charges the storage capacitor through the first thin film transistor, and simultaneously controls the second thin film transistor to operate in a saturation region, and a constant voltage signal connected to a power cable outputting a driving current through the second thin film transistor;
an operation in which the first thin film transistor is turned off, the storage capacitor discharges to make the second thin film transistor continue to operate in the saturation region, and the constant voltage signal connected to the power cable outputs the driving current through the second thin film transistor;
an operation in which when the first cathode signal, the second cathode signal, the third cathode signal, and the fourth cathode signal are all powered up, and power supply voltages are consistent, the first display panel and the second display panel of the double-sided display panel display identical images;
an operation in which when the first cathode signal is powered up, the second cathode signal is powered off, the third cathode signal is powered off, the fourth cathode signal is powered up, and power supply voltages of the first cathode signal and the third cathode signal are different, then the first display panel and the second display panel of the double-sided display panel display different images;
an operation in which when the first cathode signal is powered up, the second cathode signal is powered off, the third cathode signal is powered up, the fourth cathode signal is powered off, and the power supply voltages of the first cathode signal and the third cathode signal are identical, the first display panel of the double-sided display panel displays an image, and the second display panel of the double-sided display panel does not display an image;
an operation in which when the first cathode signal is powered off, the second cathode signal is powered up, the third cathode signal is powered off, the fourth cathode signal is powered up, and power supply voltages of the second cathode signal and the fourth cathode signal are identical, then the second display panel of the double-sided display panel displays an image, and the first display panel of the double-sided display panel does not display an image.

10. A display device, comprising a double-sided display panel, the display panel comprising a substrate, and further comprising a first display panel and a second display panel that are arranged opposite to each other; wherein the first display panel and the second display panel are arranged on the substrate; wherein a display surface of the first display panel and a display surface of the second display panel are arranged to face away from each other; wherein the first display panel comprises a first anode layer, a first light-emitting layer, and a first cathode layer that are stacked in sequence, and wherein the second display panel comprises a second anode layer, a second light-emitting layer, and a cathode layer that are stacked in sequence;
wherein the first anode layer and the second anode layer are connected to each other; wherein an orthogonal projection of the first anode layer on the substrate overlaps or coincides with an orthogonal projection of the second anode layer on the substrate.

11. The display device as recited in claim 10, wherein the first anode layer and the second anode layer are respectively arranged on two sides of the substrate that face away from each other, wherein there is defined a through hole in the substrate, wherein the first anode layer and the second anode layer are connected through the through hole;
wherein the first display panel comprises a first pixel, wherein the second display panel comprises a second pixel, wherein the first pixel and the second pixel are arranged on opposite sides of the substrate; wherein the first pixel comprises a first anode, a first light-emitting element, and a first cathode that are stacked in sequence; wherein the second pixel comprises a second anode, a second light-emitting element, and a second cathode that are stacked in sequence; wherein the first anode is arranged in the first anode layer, wherein the second anode is arranged in the second anode layer, wherein the first light-emitting element is arranged in the first light-emitting layer, wherein the second light-emitting element is arranged in the second light-emitting layer, wherein the first cathode is arranged in the first cathode layer, wherein the second cathode is arranged in the second cathode layer; wherein the first anode and the second anode are connected through the through hole; wherein the first cathode and the second cathode are independently controlled.

12. The display device as recited in claim 11, wherein the first display panel further comprises a third pixel, wherein the second display panel further comprises a fourth pixel; wherein the third pixel and the fourth pixel are arranged on the two sides of the substrate that face away from each other; wherein the third pixel is arranged adjacent to the first pixel, wherein the second pixel is arranged adjacent to the fourth pixel; wherein the third pixel comprises a third anode, a third light-emitting element, and a third cathode that are stacked in sequence; wherein the fourth pixel comprises a fourth anode, a fourth light-emitting element, and a fourth cathode that are stacked in sequence; wherein the through hole comprises a first through hole and a second through hole; wherein the third anode is arranged in the first anode layer, wherein the fourth anode is arranged in the second anode layer, wherein the third light-emitting element is arranged in the first light-emitting layer, wherein the fourth light-emitting element is arranged in the second light-emitting layer, wherein the third cathode is arranged in the first cathode layer, wherein the fourth cathode is arranged in the second cathode layer;
wherein the first anode and the second anode are connected through the first through hole, wherein the third anode and the fourth anode are connected through the second through hole; and wherein the first anode and the third anode are not connected to each other, wherein the second anode and the fourth anode are not connected to each other; wherein the third cathode and the fourth cathode are independently controlled.

13. The display device as recited in claim 12, wherein the first cathode layer comprises the first cathode and the third cathode alternately arranged in a plurality of rows or columns, and wherein the first cathode and the third cathode in each row or column are each a bar-shaped structure; wherein the second cathode layer comprises the second cathode and the fourth cathode alternately arranged in a plurality of rows or columns, and wherein the second cathode and the fourth cathode in each row or column are each a bar-shaped structure.

14. The display device as recited in claim 13, wherein the double-sided display panel further comprises a data line arranged between the first anode and the substrate; wherein the data line is connected to the first anode layer, and is connected to the second anode layer through the through hole;
wherein the first anode comprises a first anode portion and a second anode portion connected to each other, wherein the second anode comprises a third anode portion and a fourth anode portion connected to each other; wherein the first through hole is disposed between the first anode and the third anode, wherein the second anode portion and the fourth anode portion are each disposed corresponding to the first through hole and are connected to each other through the first through hole;
wherein the third anode comprises a fifth anode portion and a sixth anode portion connected to each other, wherein the fourth anode comprises a seventh anode portion and an eighth anode portion connected to each other; wherein the second through hole is disposed on a side of the third anode facing away from the first anode, wherein the sixth anode portion and the eighth anode portion are each disposed corresponding to the second through hole and are connected to each other through the second through hole;
wherein a diameter of each of the first through hole and the second through hole lies in the range of 5 μm to 10 μm.

15. The display device as recited in claim 14, wherein the first display panel and the second display panel are arranged on a same side of the substrate; wherein the first display panel comprises a plurality of overhang structures and a plurality of pixel openings; wherein the plurality of overhang structures are arranged on the substrate at intervals; wherein the plurality of pixel openings are each disposed between respective two adjacent overhang structures; wherein the first anode layer and the second anode layer are connected through the plurality of overhang structures;
wherein the first display panel comprises a first pixel, wherein the second display panel comprises a second pixel; wherein the first pixel and the second pixel are stacked in sequence on a same side of the substrate; wherein the first pixel comprises a first anode, a first light-emitting element, a first cathode, and a first encapsulation layer that are stacked in sequence; wherein the second pixel comprises a second anode, a second light-emitting element, a second cathode, and a second encapsulation layer that are stacked in sequence; wherein the first anode is arranged in the first anode layer, wherein the second anode is arranged in the second anode layer, wherein the first light-emitting element is arranged in the first light-emitting layer, wherein the second light-emitting element is arranged in the second light-emitting layer, wherein the first cathode is arranged in the first cathode layer, wherein the second cathode is arranged in the second cathode layer; wherein the first anode and the second anode are connected through a respective overhang structure, wherein the first cathode and the second cathode are independently controlled.

16. The display device as claimed in claim 15, wherein the overhang structure comprises a pixel defining layer, a metal conductive layer, and a shielding layer that are stacked in sequence, wherein the metal conductive layer comprises a first metal conductive layer and a second metal conductive layer, wherein the first metal conductive layer and the second metal conductive layer are arranged on the pixel defining layer at intervals, and wherein a part of the shielding layer is disposed between the first metal conductive layer and the second metal conductive layer, wherein the second anode comprises a first anode portion, a first anode connecting portion, and a second anode connecting portion that are connected to each other, wherein the first anode connecting portion and the second anode connecting portion are arranged opposite to each other and are each connected to the first anode portion, wherein the first anode connecting portion is connected to one end of the first anode through the second metal conductive layer of an n-th overhang structure, wherein the second anode connecting portion is connected to another end of the first anode through the first metal conductive layer of an (n+1)-th overhang structure.
